(19) United States
(12) Patent Application Publication
(10) Pub. No.: US 2007/0279887 A1
(43) Pub. Date: Dec. 6, 2007

(54) WALL PLATE ASSEMBLY WITH INTEGRAL DIGITAL EXTENDER

(76) Inventors: Thomas Sullivan, Brookville, OH (US); Gary Hess, Springfield, OH (US)

Correspondence Address: DINSMORE & SHOHL LLP, ONE DAYTON CENTRE, ONE SOUTH MAIN STREET, SUITE 1300, DAYTON, OH, 45402-2023, US

(21) Appl. No.: 11/687,821

(22) Filed: Mar. 19, 2007

Related U.S. Application Data
(60) Provisional application No. 60/809,430, filed on May 30, 2006.

(51) Int. Cl. H05K 7/02

(52) U.S. Cl. 361/809; 361/760

(57) ABSTRACT

A digital extender integrated into a wall plate assembly. The assembly includes a mounting bracket, wall plate, digital extender circuitry, electrical interface and an electrically conductive cable, wire or related cable lead. The cable lead electrically connects to a signal source and to the digital extender circuitry so that it can transmit a signal from the signal source to the electrical interface through the digital extender circuitry. By making the digital extender circuitry an integral part of the assembly, difficulties associated with packaging, transporting and connecting to the signal source are reduced.

This application claims the benefit of the filing date of U.S. Provisional Application No. 60/809,430, filed May 30, 2006.

### BACKGROUND OF THE INVENTION

The present invention relates to termination points for wiring systems and, more particularly, to a wall plate assembly that extends the range of digital signals transmitted over such wiring systems.

Digital video transmission has several demonstrated performance advantages over transmission of the same content in the analog domain. One significant advantage is the pixel-for-pixel image mapping and attendant increase in resolution and color accuracy possible when a digital signal remains in the digital domain between a digital source and display. Digital video is based on transmission minimized differential signals (TMDS). To support high definition motion video, data rates up to 165 MHz (4.95 Gbs) may be required. Such high-speed signals are susceptible to degradation from attenuation, cross-talk and mismatched system impedance. These data errors will manifest themselves as sparkles in the image, pixelization and distortion of the image, or loss of the image entirely.

In general, a digital extender transfers video data from a graphics device at the source (such as the graphics card from a computer) as binary coded data, rather than as an analog signal to a remote video device, such as a monitor, television (TV) screen or the like. Experience has shown that, absent a digital extender, digital signals (such as those that come from a computer, DVD player or the like) are limited to relatively short lengths, typically no more than about five meters (i.e., approximately fifteen feet) in length. Thus, a digital extender is generally used as (among other things) an error-correction device, and is often associated with signal timing between various conductors in multi-wire conductors (such as copper twisted pair wiring or the like) over long distances. In this way, use of a digital extender promotes high signal quality regardless of the cable length. Nevertheless, traditional digital extenders tend to be cumbersome, and can either be a source of wiring problems (such as producing a tendency to separate from the wires or cables to which they are connected), as well as being difficult to integrate into cables or wiring placed in conduit. Such problems can reduce the effectiveness of conventional digital extenders.

### BRIEF SUMMARY OF THE INVENTION

The problems discussed above are overcome by the device of the present invention, which according to a first aspect thereof integrates a digital extender into a wall plate assembly that can be mounted into a conventional outlet, junction box or related termination point. In this first aspect, a wall plate assembly includes a mounting bracket with a wall plate coupled to it, digital extender circuitry and a cable lead. The assembly includes an electrical interface (for example, a digital video interface (DVI) or high definition multimedia interface (HDMI) or variations of either) that can be formed in, through or on the surface of the wall plate. The digital extender circuit is electrically coupled to the electrical interface, and is otherwise affixed to one of the other assembly components such that the digital extender circuitry forms an integral part of the assembly. The cable lead is electrically connected to and extending from the digital extender circuitry so that upon connection of the cable lead to an electrical source, a signal carried from the source is conveyed to the electrical interface through the digital extender circuit. In the present context, an electrical source need not be the location where the signal is generated, but may also include conduit (for example, in the form of electrically conductive wires, cables or the like) that conveys the signal from an originating point to the wall plate assembly. Usage of the term herein will be apparent from the context. Also as understood in the present context, components need not be of one-piece construction to be integral, but merely that they be assembled as a singular whole. In this regard, disparate pieces can be brought together to be fabricated as a single unit capable of being sold, transported, installed or removed as such. Thus, the term “integral” in conjunction with the term “assembly” refers to a collection of components so assembled as to form a complete apparatus, structure or unit thereof.

The system of the present invention will provide a simple solution for (among other things) residential and commercial digital video transfer. The digital video signal supplied by a computer, digital video disk (DVD), cable or off-air tuner or other digital video source can be connected to the system via an ordinary DVI or HDMI interconnect up to its normally-permitted (for example, five meters) length. In one configuration, the DVI can be digital-only (designated DVI-D) or any other suitable configuration. The assembly, which may include input and output wall plates and an appropriate cable, features an integrated equalizer/amplifier to correct for signal attenuation and impedance matching issues. In one preferable (although not necessary) form, the assembly includes this amplification and buffering circuitry on a circuit board that can be mounted to the mounting bracket, wall plate or an optional enclosure. This active signal correction will allow additional length (for example, up to thirty meters, or approximately one hundred feet) of signal transfer from the input wall plate to the output wall plate via runner cable or related wiring system componentry. Additional capacity (for example, three meters (i.e., approximately ten feet or more) of HDMI or DVI cable from the output wall plate to the display enables additional extension.

The runner cable and wall plate cable leads (the latter in the form of pigtails, for example) can be terminated with a DIN connector, which provides easy cable installation and a solderless termination that doesn't require the use of special tools. The connectors will also possess a locking ability to prevent inadvertent disconnection. In the present context, the term “cable lead” defines a cable, wire or related electric signal-carrying member that preferably is used as the bridge between the circuitry in the wall plate and the runner cable. In addition, an appropriate quick-connect may be used to couple the cable lead to the digital extender circuitry, circuit board or the like. Such as quick-connect can be used for strain relief or other connecting purposes.

The functional length of a system incorporating the present invention is estimated at between approximately thirty and thirty meters (approximately one hundred feet). The combination of an active input wall plate and passive output wall plate are interchangeable for position and termination, allowing for HDMI, DVI-D and HDMI-to-DVI-D combinations to suit the user's requirements. Using appropriate connectors and interface products allows the system to minimize or eliminate many of the pitfalls which currently limit digital video signal transmission in a conventional wiring application.

According to another aspect of the invention, a wiring system is disclosed. The wiring system includes a wall plate assembly and one or more wires electrically connected to the assembly. The wire can be connected to an electrical source such that upon operation of the source, the wire transmits a signal to an electrical interface in the assembly, after passing through digital extender circuitry that is integrally formed as an integral part of the assembly. The wiring system may include numerous such wall plate assemblies that can be connected to one another through the wires in either a point-to-point configuration or a point-to-multipoint configuration.

According to yet another aspect of the invention, a digital signal device is disclosed. The device is configured to extend the range of a digital signal produced thereby, and includes a source of a digital signal, one or more wires electrically connected to the source and a wall plate assembly, where the latter is generally similar to the previously-described aspects. The wires are configured to convey a digital signal emanating from the source. Optionally, an electrical travel path between the source and the electrical interface is at least fifteen feet in length. In another option, the electrical travel path between the source and the electrical interface is up to approximately one hundred feet in length. In the present context, an electrical travel path is the distance the signal travels through the wire, which may or may not be the same distance as the distance between the source and the wall plate assembly. For example, the wire may be at least partially rolled or coiled such that the distance between the source and the wall plate assembly is linearly less than the electrical travel path, sometimes considerably so. In this regard, the linear distance is less important to the aforementioned signal degradation than that of the electrical travel path.

According to yet another aspect of the invention, a method of extending the range of a digital signal is disclosed. The method includes electrically connecting a wall plate assembly to a source of the digital signal. To perform the necessary range extension, the wall plate assembly includes digital extender circuitry that is an integral part of the assembly. During operation of the source, a signal passes through the digital extender circuitry to an electrically downstream component, such as an electrical interface that makes up a portion of the wall plate assembly. The distance between the electronic source device and the wall plate assembly is defined as a first electrical travel path distance. As with the previous embodiments, the wall plate assembly includes a mounting bracket, a wall plate, an electrical interface, digital extender circuitry and a cable lead or related cable or wire that is electrically connected to the digital extender circuitry and the electrically conductive wire that is connected to the electronic source device. As will be understood by those skilled in the art, the distance that the digital extender circuitry can extend the signal may depend on the construction of the cable, where the larger the cable, the longer the signal travel path. Thus, a larger cable (for example, 24 AWG) will permit a longer travel path (between, for example, seven to ten meters) than a smaller (for example, 30 AWG, which may permit an approximately two meter travel distance). It will be similarly understood that signal travel distances are also impacted by the quality of the electronic source device.

Optionally, the method further includes electrically connecting an electronic receiving device to the wall plate assembly along a second electrical travel path distance. The electronic receiving device is signally compatible with the electronic source device. The first electrical travel path distance is greater than that of a connection that does not employ the digital extender circuitry. In one form, the first travel path distance is approximately fifteen feet, and could be considerably longer, such as up to approximately one hundred feet. The second electrical travel path distance can further extend the length through which the digital signal is transmitted, up to approximately thirty feet. In one form, the digital extender circuitry can be placed or formed on a circuit board. The circuit board can be mounted to the mounting bracket, wall plate or other suitable components on the assembly. The digital extender circuitry can be substantially enclosed in a case, box or related structure that in turn can be secured to the mounting bracket or other structure. As with the wiring system discussed above, the method may include connecting numerous wall plate assemblies in either a point-to-point or a point-to-multipoint configuration.

### BRIEF DESCRIPTION OF THE SEVERAL VIEWS OF THE DRAWINGS

The following detailed description of specific embodiments of the present invention can be best understood when read in conjunction with the following drawings, where like structure is indicated with like reference numerals and in which:

FIG. 1 illustrates a front perspective view of a wall plate assembly with digital extender according to one embodiment of the present invention;

FIG. 2 illustrates a rear perspective view of the assembly of FIG. 1;

FIG. 3 illustrates a side elevation view of the assembly of FIG. 1;

FIG. 4 illustrates a cutaway view of the assembly of FIG. 3;

FIG. 5A illustrates a mounting bracket with the digital extender attached thereto;

FIG. 5B illustrates a back shell enclosure for covering the digital extender of FIG. 5A;

FIG. 6 illustrates a side exploded elevation view of the assembly similar to that of FIG. 3, this time without the DIN connector;

FIG. 7 illustrates the assembly of FIG. 1 mounted into a single-gang outlet box;

FIG. 8 illustrates a side cutaway view of the assembly of FIG. 7;

FIG. 9 illustrates the assembly of FIG. 1 mounted to a double-gang outlet box;

FIG. 10 illustrates a side cutaway view of the assembly of FIG. 9; and

FIGS. 11A through 11C show various views of a wall plate assembly with digital extender according to another embodiment of the present invention; and

FIG. 12 shows a house using premise wiring and one embodiment of the wall plate assembly of the present invention.

### DETAILED DESCRIPTION OF THE PREFERRED EMBODIMENTS

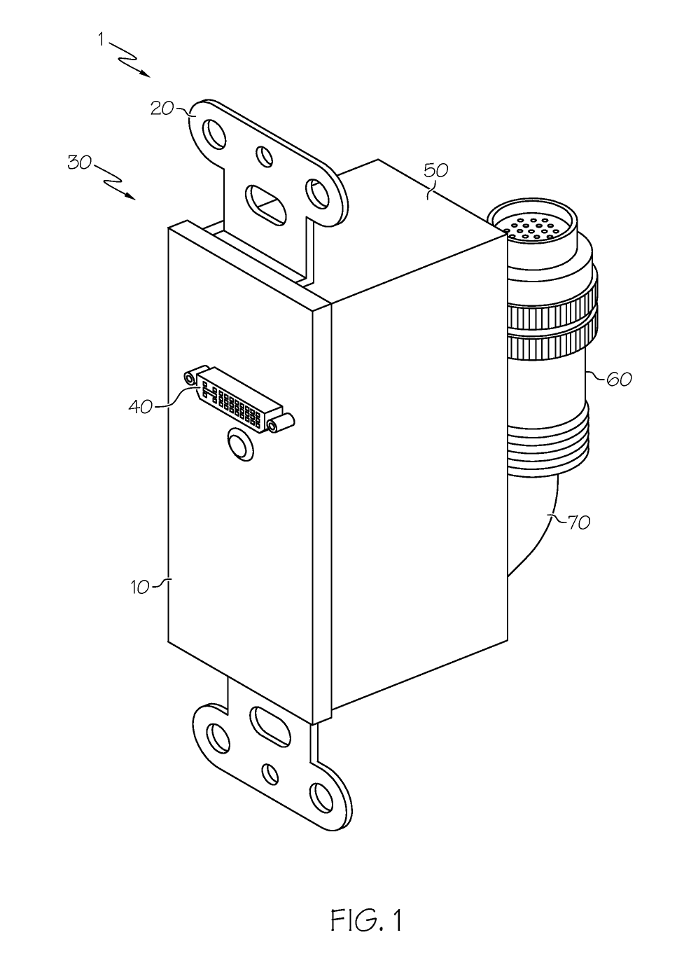

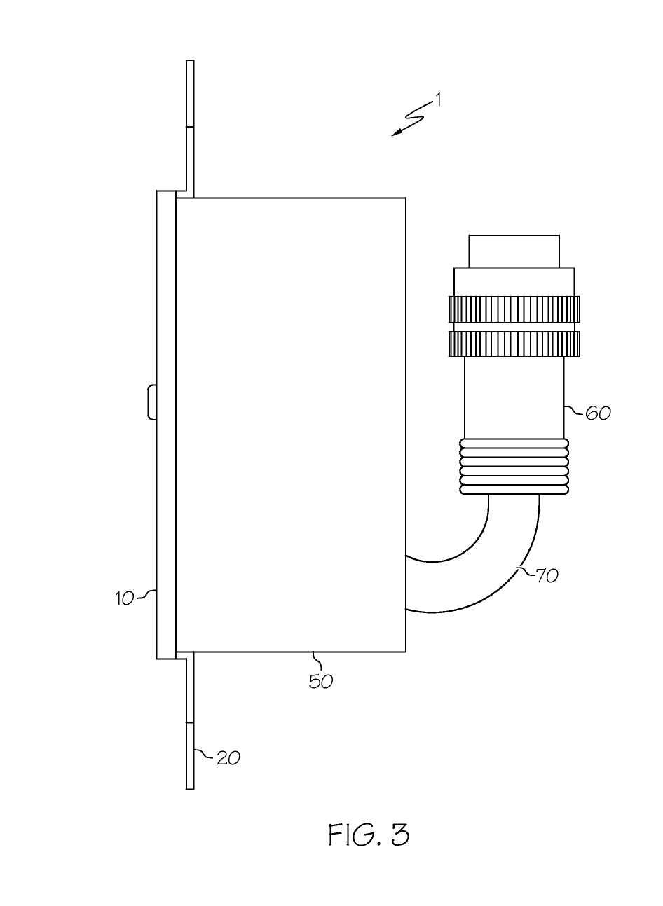

Referring first to FIGS. 1 through 3, various views of the wall plate assembly 1 are shown, where the assembly 1 includes a wall plate 10, mounting bracket 20, digital extender (in the form of a printed circuit board that may include other electronic circuitry) 30 mounted to the mounting bracket 20, an interface 40 (presently shown as a DVI interface), enclosure (also called a case or a back shell) 50 for containing the digital extender 30 and a cable lead 70 that is terminated with connector 60. In a first embodiment of the assembly 1, the cable lead 70 enters through a recessed rectangular cutout formed in the back of enclosure 50 to make a connection of the individual wires 75 therein to the appropriate components of the digital extender 30. As such, cable lead 70 may be in a pigtail shape. Although not shown, enclosure 50 may be constructed without the cutout so that the cable lead 70 enters in a generally horizontal way through an aperture formed directly in the rear wall of the enclosure 50.

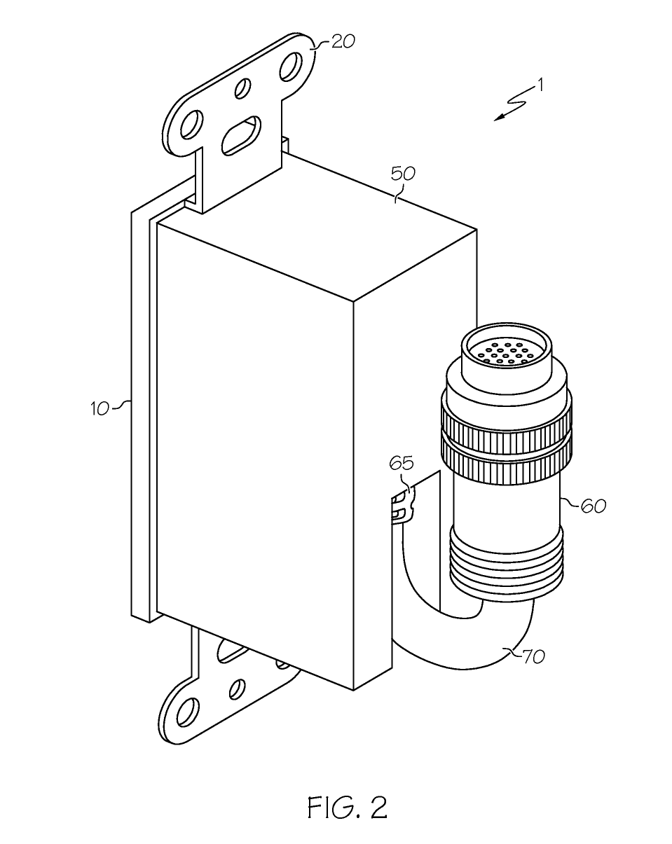

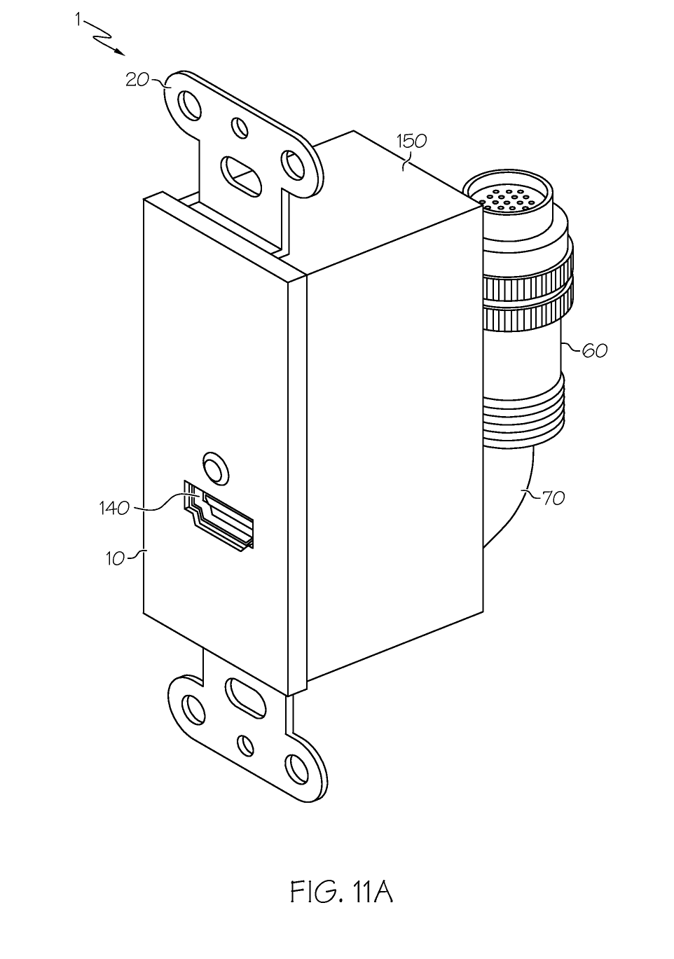

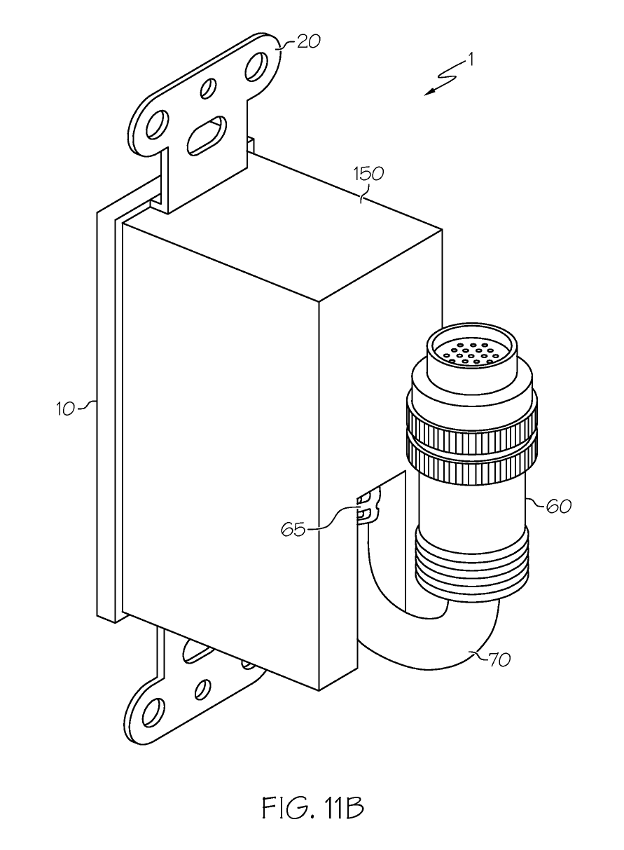

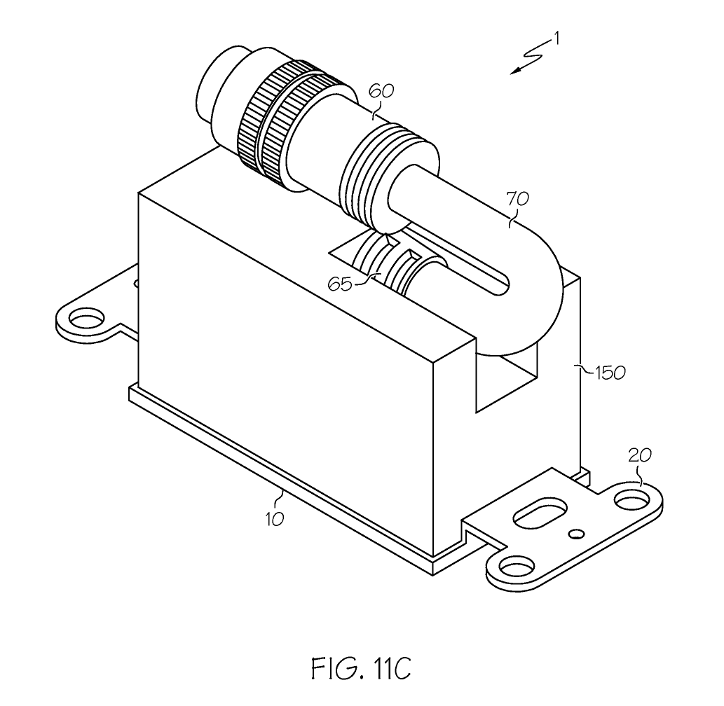

Referring next to FIGS. 11A through 11C, an alternate embodiment of the wall plate assembly 1 is shown with a different interface 140 (presently shown as an HDMI interface) and enclosure 150. As with enclosure 50 of FIGS. 1 through 3, the enclosure 150 includes a rearward-facing rectangular cutout to accommodate a cable lead 70 that is vertically mounted to the circuit board (not presently shown), rather than the rearward, horizontal mount that may necessitate additional front-to-back depth in mounting. Also in a manner generally similar to that of FIG. 2, the cable lead 70 shown in FIG. 11B may be in a pigtail shape to fit within the space created by the rectangular cutout in enclosure 50.

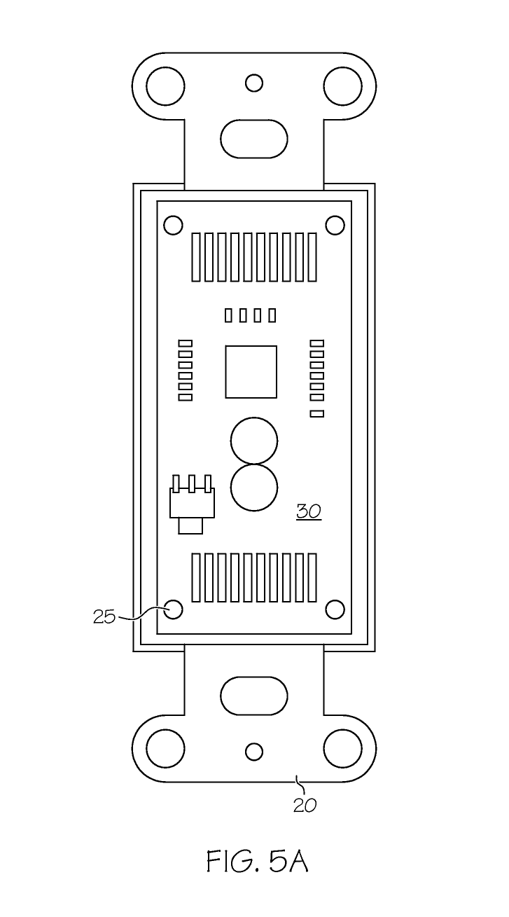

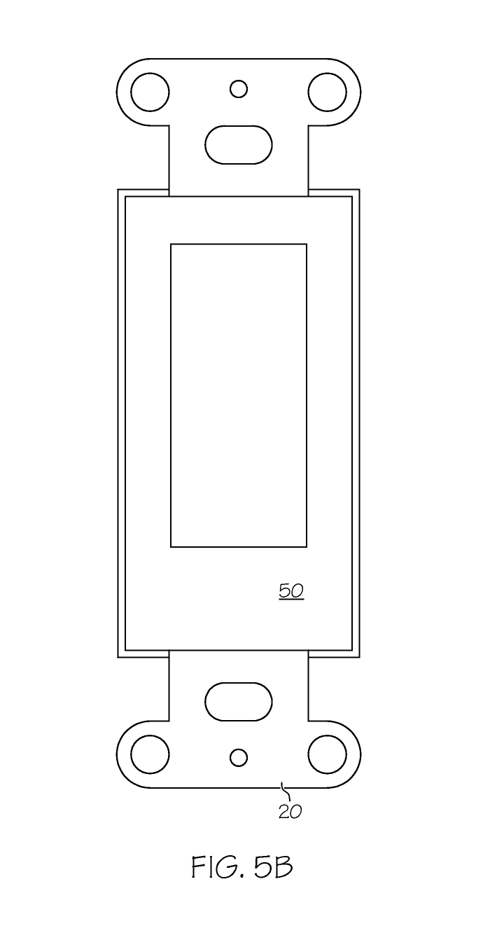

Referring with particularity to FIG. 5A, in the present disclosure, a digital extender 30 transfers video data coming from a graphics device (not shown, but such as the graphics card from a computer) as binary coded data, rather than as an analog signal. The digital extender 30 includes amplification and buffering circuitry within the wall plate assembly. This technology is commonly known to individuals skilled in the art. For example, there may be a single integrated circuit on the circuit board that is responsible for buffering, error correction and amplification. Thus, the digital extender 30 is generally used as (among other things) an error-correction device, often associated with signal timing between various conductors in multi-wire conductors (such as copper twisted pair wiring or the like) over long distances. Experience has shown that, absent a digital extender 30, digital signals (such as those that come from a computer, DVD player or the like) are limited to relatively short lengths, typically no more than about five meters in length. In this way, use of digital extender 30 promotes high signal quality regardless of the cable length. As shown with particularity in FIG. 5B, enclosure 50 (which may be made from a plastic, among other relatively rigid, inexpensive materials) is used to cover digital extender 30, providing protection thereto.

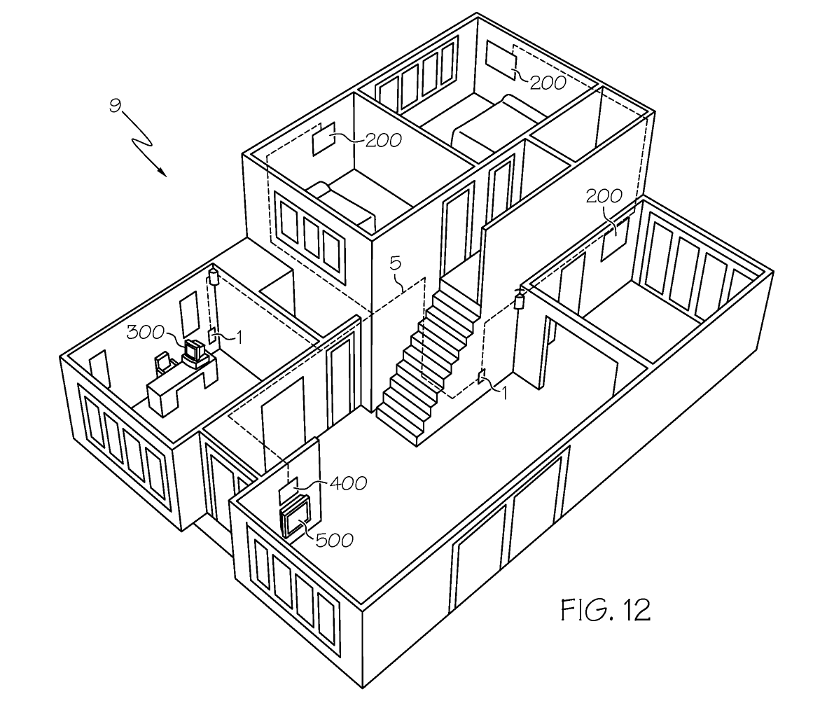

Referring again to FIGS. 1 and 11A, at one signal end of the wall plate assembly 1, the interface 40 can take on numerous forms, such as the DVI of FIG. 1 and the HDMI of FIG. 11A, the latter of which is an industry-standard digital audio/video interface that can be used between any compatible digital sources, such as a computer, set-top box, DVD player, receiver and TV or related monitor. HDMI is compatible with DVI, which are commonly used on computer monitors and graphics cards. It will be appreciated that either type of connection could be used in the present invention. At the other signal end of the wall plate assembly 1, the connector 60 is a Deutsches Institut fur Normung (DIN) connector well-known in the art that can be used to electrically attach the cable lead 70 to a runner or related cable in the wiring system 5 that is shown generally in FIG. 12. As presently shown, wall plate assembly 1 defines a portion of a point-to-point system. Although not shown, it will also be appreciated by those skilled in the art that wall plate assembly 1 and the accompanying digital extender circuitry may also be used as part of a more centralized system such as a point-to-multipoint configuration. For example, the present system can be used with selector switches, distribution amplifiers and ancillary equipment to accommodate multiple inputs and outputs.

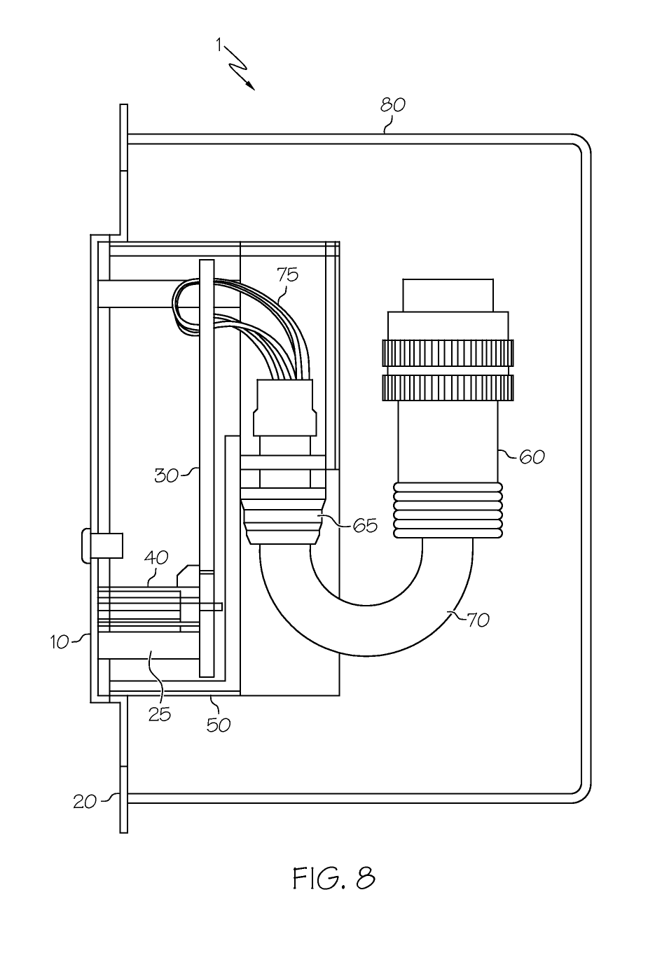

Referring with particularity to FIG. 8, a strain relief 65 can be used to join cable lead 70 to digital extender 30. Strain relief 65 keeps the cable in position so that movement cannot cause individual wires 75 from pulling loose from the digital extender 30. The strain relief 65 defines a terminal end of a length of cable lead 70 that can be coupled to the wiring system 5 through connector 60, where the wiring system 5 is conveniently run throughout a premise. In addition to the strain relief 65, quick-connects may also be used to facilitate ease of connection and disconnection. For example, the DIN connector 60 may be used as a quick-connect to the cable lead 70, where the cable lead 70 passes through the strain relief 65 that is held in position by its mounting relationship with enclosure 50. The opposite terminal end of the length of cable or wiring used in the airing system 5 can also terminate with a quick-connect and, as such, can interface with another quick-connect cable or a quick-connect electrical connector of an additional wall plate assembly according to the present invention. In this manner, wall plate assemblies 1 according to the present invention enable relatively rapid and simple premise wiring.

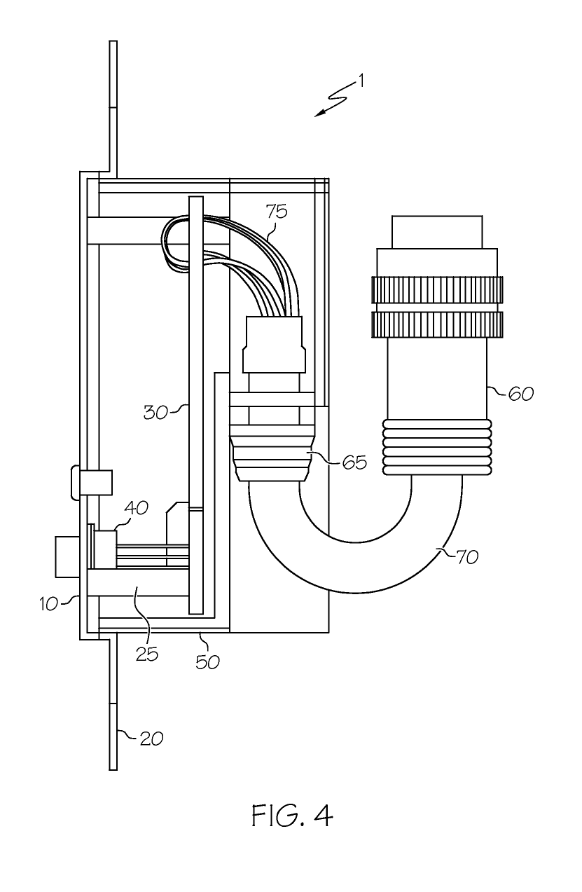

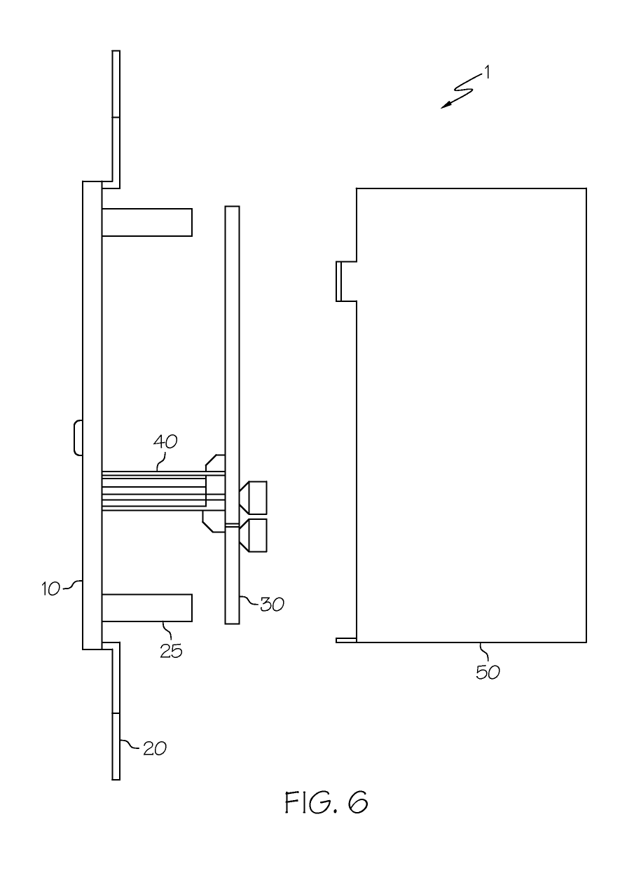

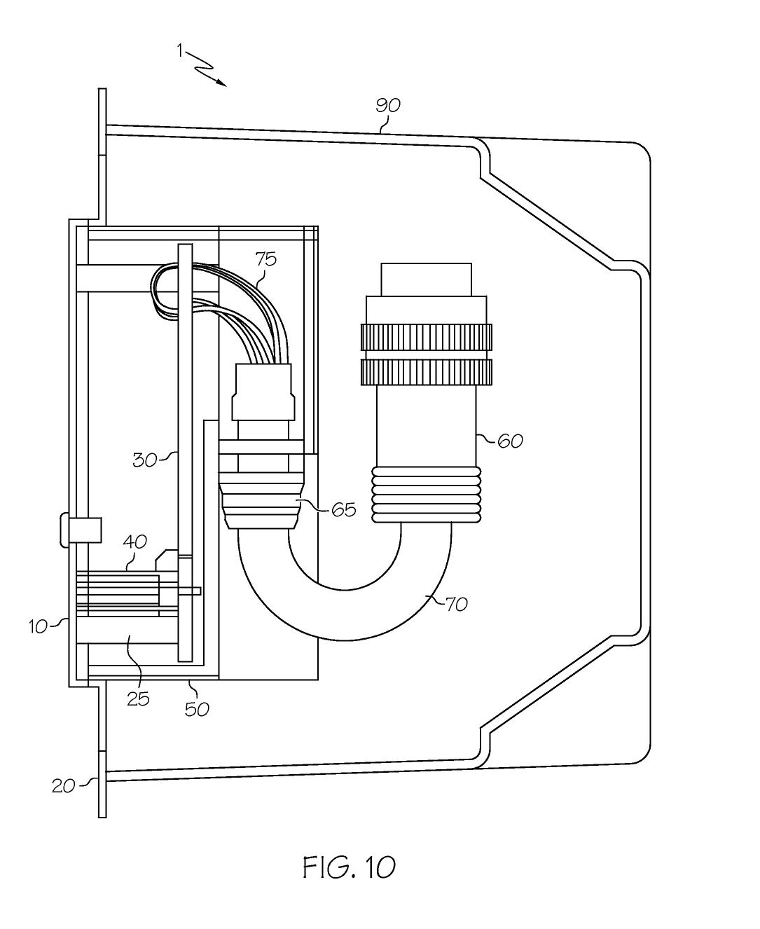

Referring next to FIGS. 4, 6 and 10 (as well as FIG. 8), the integral formation of the circuit board (on which the digital extender circuitry 30 is preferably mounted) to the remainder of the wall plate assembly 1 is shown. In one form of attachment, the circuit board is mounted to the mounting bracket 20 via posts 25 that form a unitary structure with and extend rearwardly from the back of mounting bracket 20. The posts 25 may be tubular such that the rearward-most end may accept threaded screws, rivets or other such fasteners to secure the circuit board to the mounting bracket 20. It will be appreciated by those skilled in the art that other securing means may be used, including glue or related adhesives, welding, soldering or the like.

It will be appreciated by those skilled in the art that wall plate assemblies 1 according to the present invention can be configured to define a variety of connector types and configurations, whether they be for audio, visual, radio-frequency (RF) or other types of electrical signals. It is also noted that the concepts of the present invention, where a quick-connect is integrated with the assembly 1, will have additional applicability to fiber optic transmission lines and connectors.

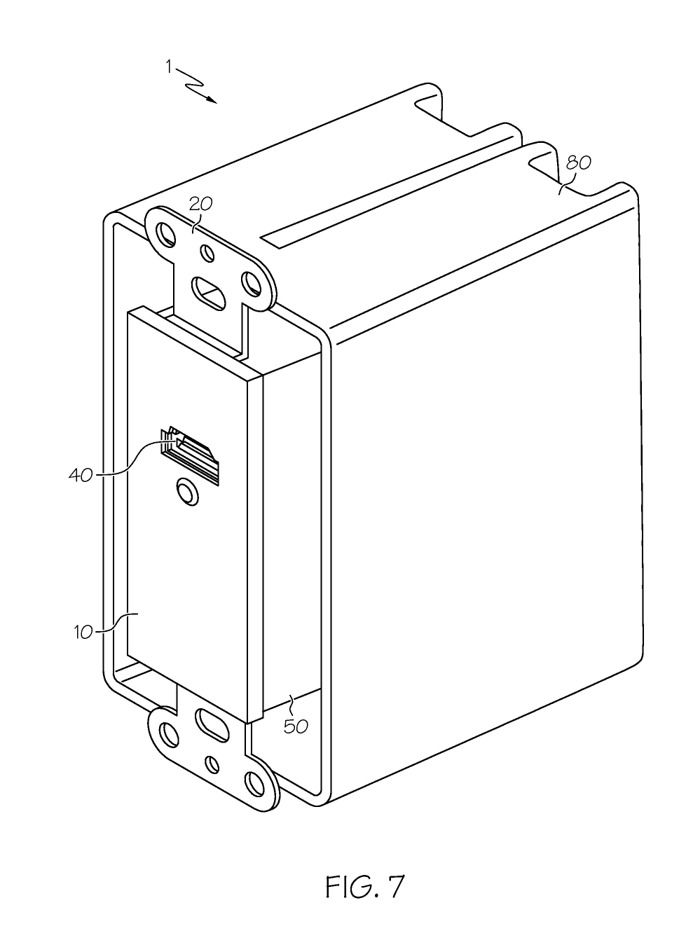

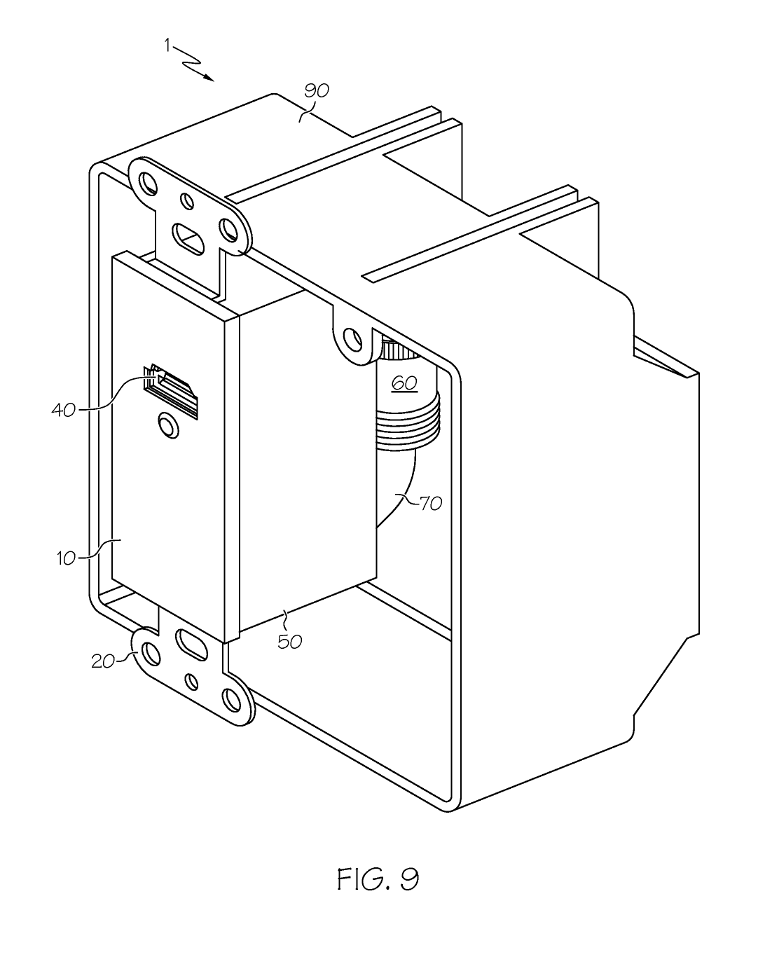

Referring with particularity to FIGS. 7 and 9, placement of the wall plate assembly 1 into gang boxes 80 (for the single-gang outlet box) and 90 (for the double-gang outlet box) is shown, where tubular mounts (not shown) can be formed in the gang boxes to facilitate attachment of the assembly 1 to the boxes 80, 90 with conventional fasteners, such as screws. As shown with particularity in FIG. 8, the boxes are spacious enough such that upon placement of the assembly 1 therein, cable lead 70 and connector 60 can be positioned to improve connectivity to a runner cable (not shown) that is part of the wiring system 5.

It is noted that any appendices or attachments to the above description of the present invention form a part of the description and should be considered part of the present application. Having described the invention in detail and by reference to specific embodiments thereof, it will be apparent that modifications and variations are possible without departing from the scope of the invention defined in the appended claims. More specifically, although some aspects of the present invention are identified herein as preferred or particularly advantageous, it is contemplated that the present invention is not necessarily limited to these preferred aspects of the invention. For example, it is noted that the electrical connectors, the electrical wiring, and the male and female quick connect connectors illustrated in the figures can be presented in a variety of configurations without departing from the scope of the present invention.

What is claimed is:

1. A wall plate assembly comprising:
a mounting bracket;
a wall plate coupled to said mounting bracket and defining an electrical interface therein;
digital extender circuitry electrically coupled to said electrical interface such that said digital extender circuitry is an integral part of said assembly; and
a cable lead electrically connected to and extending from said digital extender circuitry, said cable lead configured such that upon connection to an electrical source, a signal carried therethrough is conveyed to said electrical interface through said digital extender circuitry.

2. The wall plate assembly of claim 1, wherein said digital extender circuitry is mounted to a circuit board.

3. The wall plate assembly of claim 2, wherein said circuit board is attached to said wall plate.

4. The wall plate assembly of claim 2, wherein said cable lead is soldered to said circuit board.

5. The wall plate assembly of claim 1, wherein said electrical interface and said wall plate define a front face of said wall plate assembly.

6. The wall plate assembly of claim 1, further comprising a quick-connect disposed between said digital extender circuitry and said cable lead.

7. The wall plate assembly of claim 1, further comprising an enclosure mounted to said mounting bracket and configured to contain said digital extender circuitry therein.

8. A wiring system comprising:
a wall plate assembly comprising:
a mounting bracket;
a wall plate coupled to said mounting bracket and defining an electrical interface therein;
digital extender circuitry electrically coupled to said electrical interface such that said digital extender circuitry is an integral part of said assembly; and
a cable lead electrically connected to said digital extender circuitry; and
at least one wire electrically connected to said cable lead, said at least one wire configured such that upon connection to an electrical source, a signal carried therethrough is conveyed to said electrical interface through said digital extender circuitry.

9. The wiring system of claim 1, further comprising a plurality of wall plate assemblies connected to one another through said at least one wire in a point-to-point configuration.

10. The wiring system of claim 1, further comprising a plurality of wall plate assemblies connected to one another through said at least one wire in a point-to-multipoint configuration.

11. A digital signal device comprising:
a source of a digital signal;
at least one wire electrically connected to said source and configured to convey a digital signal emanating therefrom; and
a wall plate assembly comprising:
a mounting bracket;
a wall plate coupled to said mounting bracket and defining an electrical interface therein;
digital extender circuitry electrically coupled to said electrical interface such that said digital extender circuitry is an integral part of said assembly; and
a cable lead electrically connected to said digital extender circuitry and to said at least one wire such that said digital signal is conveyed to said electrical interface through said digital extender circuitry.

12. The device of claim 11, wherein an electrical travel path between said source and said electrical interface is at least fifteen feet in length.

13. The device of claim 11, wherein said electrical travel path between said source and said electrical interface is up to approximately one hundred feet in length.

14. A method of extending the range of a digital signal, said method comprising electrically connecting a wall plate assembly to a source of said digital signal, said wall plate assembly comprising:
a mounting bracket;
a wall plate coupled to said mounting bracket and defining an electrical interface therein;
digital extender circuitry electrically coupled to said electrical interface such that said digital extender circuitry is an integral part of said assembly; and
a cable lead electrically connected to and extending from said digital extender circuitry, said cable lead configured such that upon connection to said source, a signal carried through said cable is conveyed to said electrical interface through said digital extender circuit.

15. The method of claim 14, further comprising electrically connecting an electronic receiving device that is signally compatible with said source to said wall plate assembly along a second electrical travel path distance.

16. The method of claim 14, wherein said first electrical travel path distance is greater than approximately fifteen feet.

17. The method of claim 14, wherein said first electrical travel path distance is up to approximately one hundred feet.

18. The method of claim 14, wherein said second electrical travel path distance is up to approximately ten feet.

19. The method of claim 14, further comprising substantially disposing said digital extender circuitry on a circuit board.

20. The method of claim 19, further comprising substantially enclosing said digital extender circuitry in an enclosure, and securing said enclosure to said mounting bracket.

21. The method of claim 14, further comprising connecting a plurality of wall plate assemblies to one another in either a point-to-point or a point-to-multipoint configuration.
